(19) United States
(12) Patent Application Publication
(10) Pub. No.: US 2013/0063116 A1
(43) Pub. Date: Mar. 14, 2013

(54) TRUE REVERSE CURRENT BLOCKING SYSTEM

(71) Applicants: Ni Sun, Sunnyvale, CA (US); Xinkuan Han, Shanghai (CN); Jun Fan, Shanghai (CN)

(72) Inventors: Ni Sun, Sunnyvale, CA (US); Xinkuan Han, Shanghai (CN); Jun Fan, Shanghai (CN)

(73) Assignee: FAIRCHILD SEMICONDUCTOR CORPORATION, San Jose, CA (US)

(21) Appl. No.: 13/545,936

(22) Filed: Jul. 10, 2012

Related U.S. Application Data
(60) Provisional application No. 61/534,653, filed on Sep. 14, 2011.

(51) Int. Cl. G05F 1/625; H03K 17/687

(52) U.S. Cl. 323/284; 327/434

(57) ABSTRACT

Devices, systems and methods are provided for a switch to perform true reverse current blocking (TRCB). The device may include a PMOS switch, including a source port, a drain port, a gate port and an n-well region; an input voltage port coupled to the source port; an output voltage port coupled to the drain port; a switch control port coupled to the gate port; and comparator circuitry configured to compare an input voltage at the input voltage port with an output voltage at the output voltage port and select a maximum of the input voltage and the output voltage. The comparator circuitry may be further configured to couple the selected maximum to the n-well region.

### CROSS REFERENCE TO RELATED APPLICATIONS

This application claims the benefit of U.S. provisional patent application Ser. No. 61/534,653 filed Sep. 14, 2011, which is incorporated fully herein by reference.

### FIELD

The present disclosure relates to a reverse current blocking system, and more particularly, to a true reverse current blocking system.

### BACKGROUND

Load switches typically link a power supply with a device to be powered (a load) and provide switching control to couple or de-couple the load from the supply based on a switch control signal. Examples loads that may be controlled by a load switch include portable devices such as phones, digital cameras, media players, Global Positioning System (GPS) receivers and portable games. Load switches may provide limited or no protection, however, against reverse current flow from the load back to the power supply, which can damage sensitive and/or valuable components. This lack of reverse current flow protection is particularly common when the switch is in an off or open state.

### SUMMARY

Generally, this disclosure provides a system for true reverse current blocking in a power load switch. Load switches may be used to connect and disconnect a DC power source, at the input of the load switch, to a load at the output of the load switch that needs to receive power. Load switches also provide protection in the form of reverse current blocking (RCB) which prevents current from flowing back from the load, which is connected to the V_{OUT} port of the load switch, to the input port of the load switch, V_{IN}, the source voltage supply. Such reverse current, if not blocked, could damage the power supply or other circuitry on the input side of the load switch. This is of particular concern in battery powered applications. According to embodiments of the present disclosure, reverse current blocking is provided, regardless of the state of the load switch being open or closed (i.e., on or off). This type of RCB, which provides protection whether the switch is on or off, is referred to as true reverse current blocking (TRCB).

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 illustrates a top level block diagram consistent with various embodiments of the present disclosure;

FIG. 2 illustrates a circuit diagram consistent with various embodiments of the present disclosure;

FIG. 3 illustrates a circuit diagram consistent with various embodiments of the present disclosure;

FIG. 4 illustrates a functional block diagram consistent with various embodiments of the present disclosure; and

FIG. 5 illustrates a flowchart of operations of another exemplary embodiment consistent with the present disclosure.

Although the following Detailed Description will proceed with reference being made to illustrative embodiments, many alternatives, modifications, and variations thereof will be apparent to those skilled in the art.

### DETAILED DESCRIPTION

Generally, this disclosure provides a system for true reverse current blocking in a power load switch. Load switches may be used to connect and disconnect a DC power source, at the input of the load switch, to a load at the output of the load switch that needs to receive power. Load switches also provide protection in the form of reverse current blocking (RCB) which prevents current from flowing back from the load, which is connected to the V_{OUT} port of the load switch, to the input port of the load switch, V_{IN}, the source voltage supply. Such reverse current, if not blocked, could damage the power supply or other circuitry on the input side of the load switch. This is of particular concern in battery powered applications. According to embodiments of the present disclosure, reverse current blocking is provided, regardless of the state of the load switch being open or closed (i.e., on or off). This type of RCB, which provides protection whether the switch is on or off, is referred to as true reverse current blocking (TRCB).

TRCB can be applied to a wide variety of applications including universal serial bus (USB) power supply designs, where reverse current blocking is desirable to protect a USB host from being damaged by reverse current flow on the bus voltage line (VBUS) of the USB. Other applications where TRCB switches may be useful include personal digital assistant (PDA) handheld devices, cell phones, global positioning system (GPS) handheld devices, digital cameras, peripheral ports and accessories, portable medical equipment and hot-swap supplies.

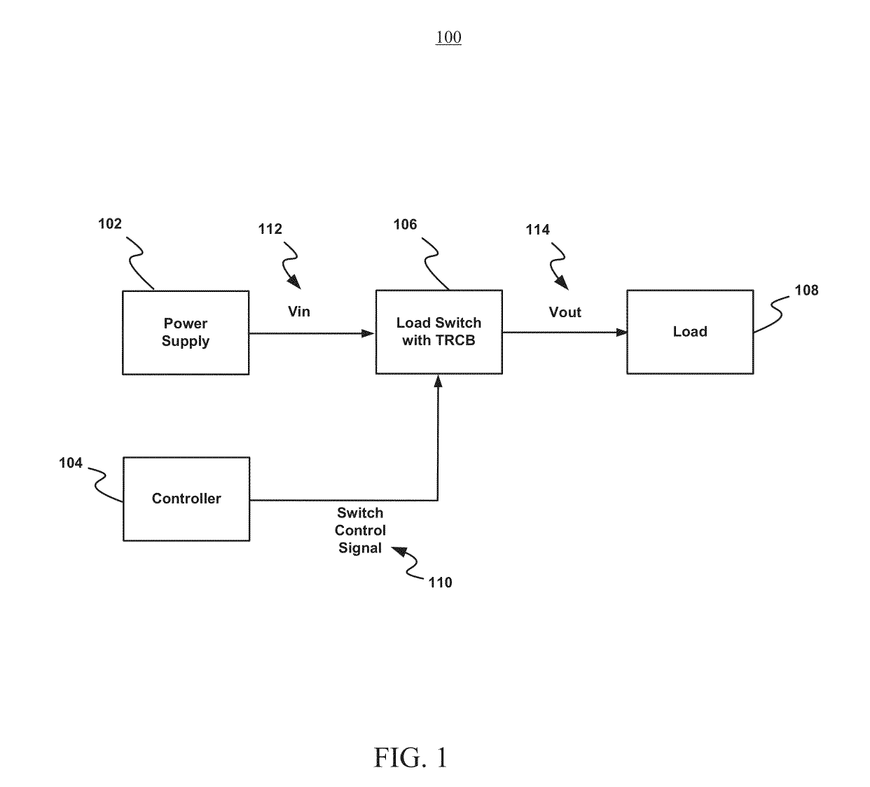

FIG. 1 illustrates a top level system diagram 100 of one exemplary embodiment consistent with the present disclosure. Shown is a load switch 106 that provides TRCB capability as will be described in greater detail below. The load switch 106 is coupled to a power supply voltage source 102, which, in some embodiments, may be a battery, providing an input voltage Vin 112 to an input port on the load switch 106. The load switch is also coupled to a load 108 to which power may be supplied through an output port providing output voltage Vout 114. The load switch 106 may operate under the control of a switch control signal 110, provided by a controller circuit 104, which may cause the load switch 106 to open or close. The controller circuit 104 may be circuitry associated with the power supply 102, the load 108 or any other suitable device intended to control the load switch. The TRCB capability of the load switch 106 provides reverse current blocking protection to the power supply 102 whether the switch 106 is open or closed.

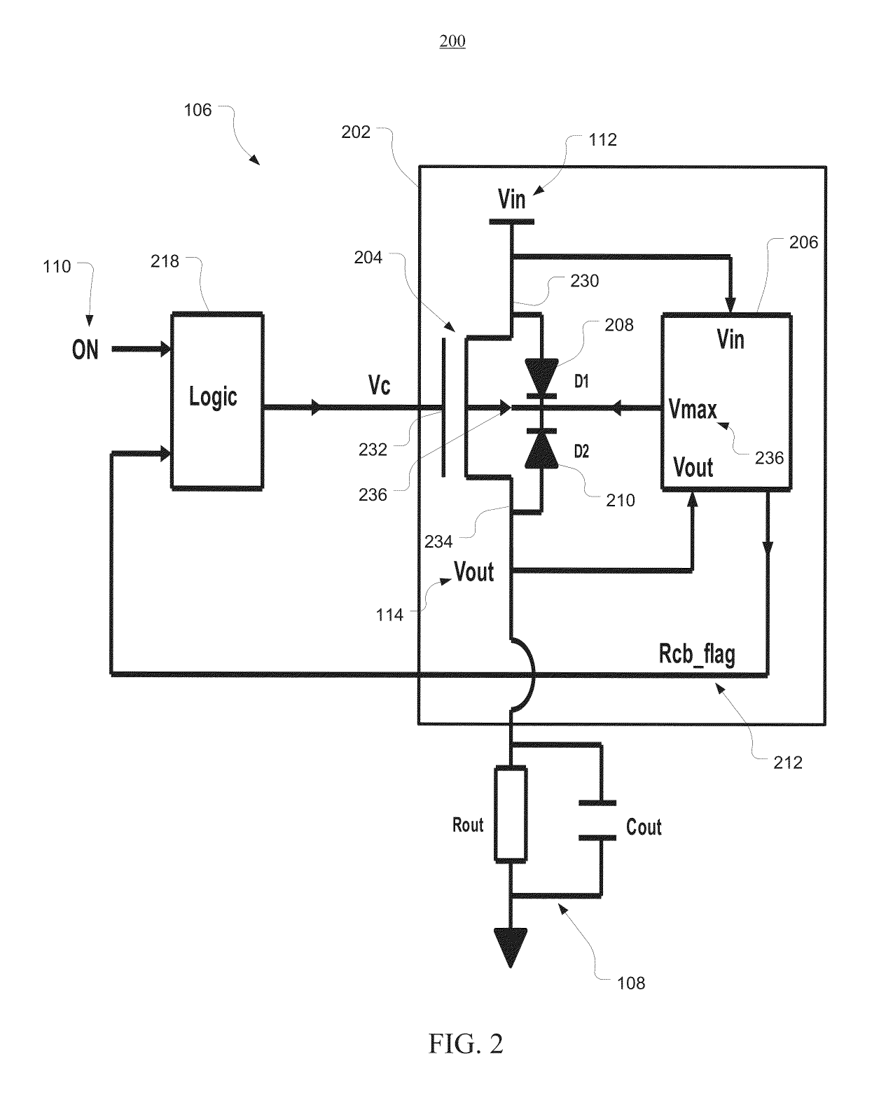

FIG. 2 illustrates a circuit diagram 200 consistent with various embodiments of the present disclosure. Circuit diagram 200 illustrates a TRCB circuit 202 comprising a p-channel metal-oxide-semiconductor field-effect-transistor (PMOS) switch 204, a comparator 206 and diodes D1 208 and D2 210. Also shown are the switch input voltage Vin 112 and output voltage Vout 114 which is coupled to an output load 108 modeled by a resistor-capacitor (RC) network including Rout and Cout. PMOS switch 204 has a source port 230, a drain port 234 and a gate port 232. The gate 232 controls current flow from the source 230 to the drain 234. That is to say, if the gate 232 is on, the switch 204 is turned on and current will flow from Vin 112 to Vout 114. If the gate 232 is off, the switch 204 is turned off and current flow through the switch will be substantially blocked. In practice, however, PMOS switches exhibit parasitic diode effects which can result in reverse current leakage when Vout 114 is greater than Vin 112, even though switch 204 is off. The parasitic diode effect is created by a body diode which exists in CMOS technology.

Comparator 206 is configured to monitor and compare Vin 112 and Vout 114 and to generate a Vmax output 236 that is set to the larger of Vin 112 and Vout 114. Vmax 236 is connected to the n-well region 236 of switch 204 so that one of the p-n junctions of the switch (the side with the higher voltage, either Vin 112 or Vout 114) is shorted out. For example, if the switch 204 is off and Vout 114 is greater than Vin 112, then Vmax 236 will be set to Vout 114 causing diode D2 210 to be shorted while diode D1 208 blocks current flow in the direction from Vout 114 to Vin 112.

Comparator 206 also generates an RCB flag 212 which signals that reverse current is being blocked when Vout 114 is greater than Vin 112. The RCB flag 212 is logically combined with the ON signal 110 at logic block 218 to negate the ON signal 110 during times when reverse current is being blocked. This provides additional TRCB protection by preventing switch 204 from being turned on when Vout 114 is greater than Vin 112.

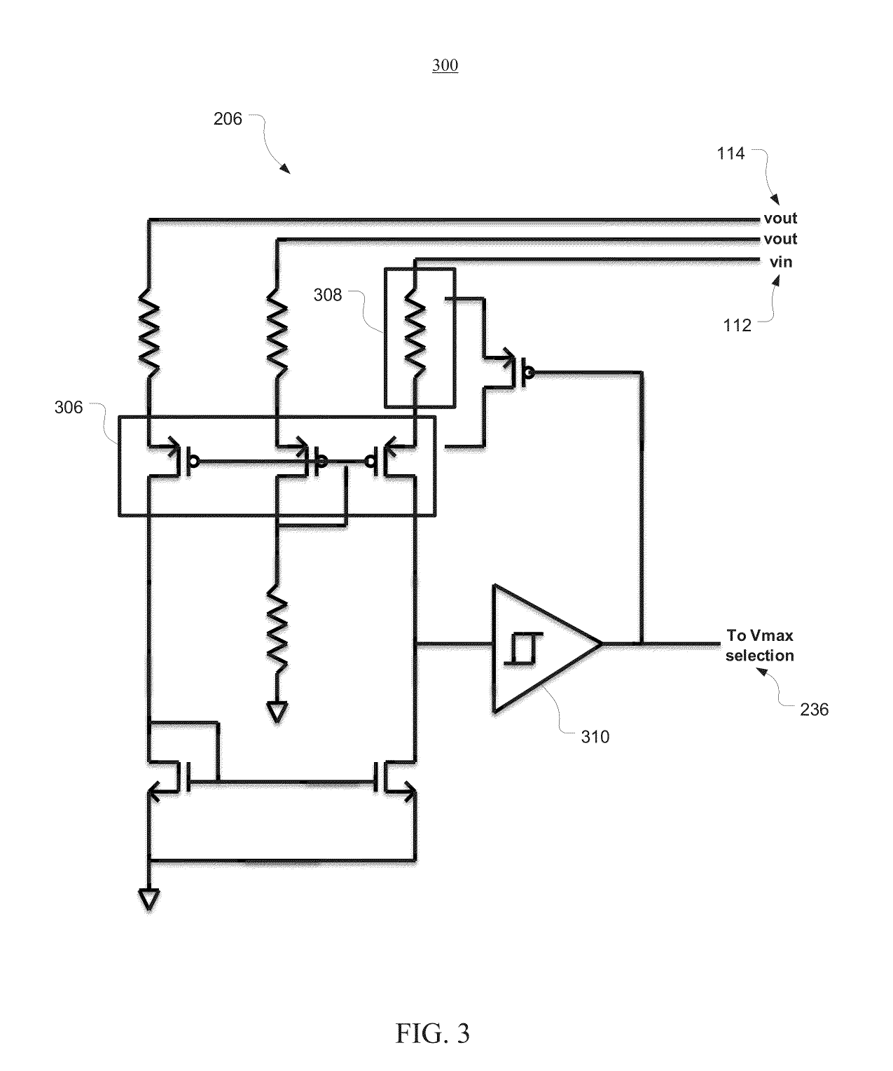

FIG. 3 illustrates a circuit diagram 300 consistent with various embodiments of the present disclosure. Circuit diagram 300 illustrates, in greater detail, an embodiment of comparator 206. Circuit module 306 implements a cascade realization of a comparator circuit to operate on signals Vout 114 and Vin 112. The cascade comparator is configured as a two-stage amplifier. The two amplification stages improve input-output isolation which reduces the possibility of reverse current leakage through the comparator. Trimming resistor 308 may be provided for calibration of the comparator. Hysteresis circuit 310 may be provided to prevent false triggering of the Vmax signal 236, particularly during transition periods when the maximum value may toggle between Vin 112 and Vout 114 before settling on one or the other. A hysteresis circuit generally prevents a state change at the input from propagating to the output, unless the input has remained constant for a pre-determined or selectable period of time.

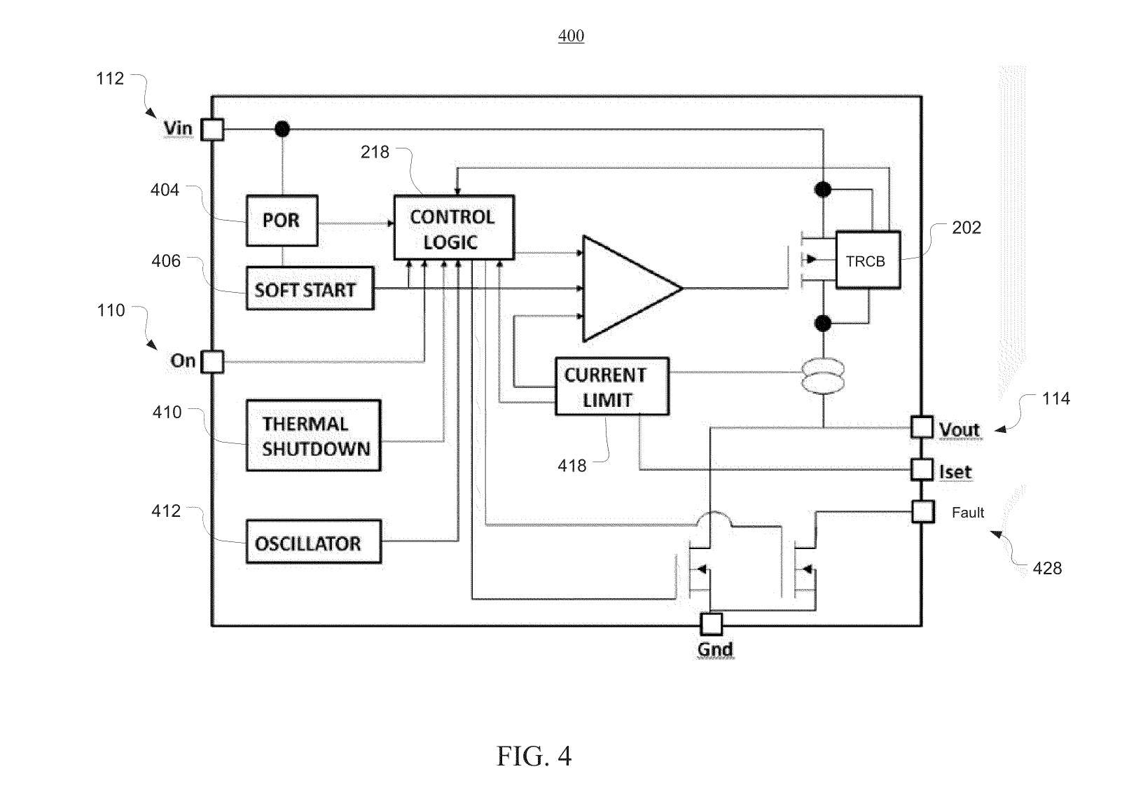

FIG. 4 illustrates a functional block diagram of a system 400 consistent with various embodiments of the present disclosure. System 400 is an embodiment of one implementation of the TRCB switch 202 in an application with supporting circuitry. A DC power supply may be connected to Vin 112, and a load may be connected to Vout 114. A switch control signal may be connected to the On port 110 to turn the TRCB switch 202 on or off, and thus allow current to flow or not flow from the DC power supply to the load. This switch control signal may be processed by control logic block 218 in conjunction with inputs from a power on reset unit 404, a soft start unit 406, a thermal shutdown unit 410, an oscillator based timing generator 412 and a current limiter unit 418. Thermal shutdown unit 410 monitors the circuit for an over-temperature condition and signals such condition to control logic unit 218. Current limiter unit 418 monitors the current flowing through the TRCB switch 202, for an over-current condition and also signals such condition to control logic unit 218. During normal operating conditions, control logic unit 218 will turn the TRCB switch 202 on or off depending on the switch control signal at the On port 110. During abnormal operating conditions, such as over-temperature or over-current, control logic unit 218 may turn the TRCB switch 202 off, regardless of the state of the switch control signal at the On port 110, and may generate a Fault signal at the Fault port 428 to signal the condition to external components as necessary. After a suitable time delay, as determined by oscillator based timing generator 412, control logic unit 218 may perform an automatic restart of the switch.

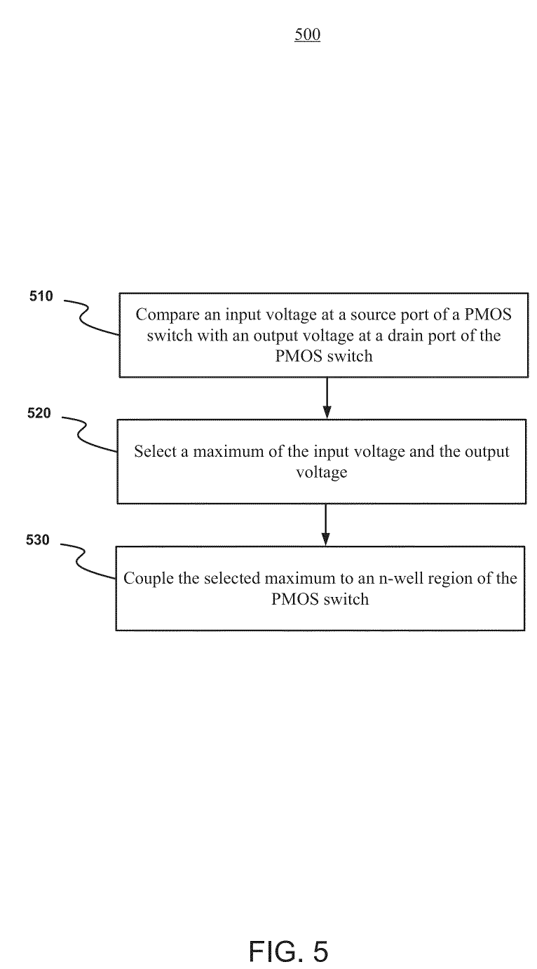

FIG. 5 illustrates a flowchart of operations 500 of an exemplary embodiment consistent with the present disclosure. At operation 510, an input voltage at a source port of a PMOS switch is compared with an output voltage at a drain port of the PMOS switch. At operation 520, a maximum of the input voltage and the output voltage is selected. At operation 530, the selected maximum of the input voltage and the output voltage is coupled to an n-well region of the PMOS switch. In some embodiments, the gate port of the PMOS switch may be turned off in response to detecting that the output voltage exceeds the input voltage.

Thus, the present disclosure provides devices, systems and methods for a switch to perform true reverse current blocking (TRCB). According to one aspect there is provided a device. The device may include a PMOS switch, including a source port, a drain port, a gate port and an n-well region. The device of this example may also include an input voltage port coupled to the source port. The device of this example may further include an output voltage port coupled to the drain port. The device of this example may further include a switch control port coupled to the gate port. The device of this example may further include a comparator circuit configured to compare an input voltage at the input voltage port with an output voltage at the output voltage port and select a maximum of the input voltage and the output voltage, and the comparator circuit is further configured to couple the selected maximum to the n-well region.

According to another aspect there is provided a method. The method may include comparing an input voltage at a source port of a PMOS switch with an output voltage at a drain port of the PMOS switch. The method of this example may also include selecting a maximum of the input voltage and the output voltage. The method of this example may further include coupling the selected maximum to an n-well region of the PMOS switch.

According to another aspect there is provided a system. The system may include a TRCB switch including a PMOS switch, including a source port, a drain port, a gate port and an n-well region. The PMOS switch of this example may also include an input voltage port coupled to the source port. The PMOS switch of this example may further include an output voltage port coupled to the drain port. The PMOS switch of this example may further include a switch control port coupled to the gate port. The PMOS switch of this example may further include a comparator circuit configured to compare an input voltage at the input voltage port with an output voltage at the output voltage port and select a maximum of the input voltage and the output voltage, and the comparator circuit is further configured to couple the selected maximum to the n-well region. The TRCB switch of this example may also include a thermal shutdown circuit configured to monitor the temperature of the TRCB switch and turn the TRCB switch off in response to the monitored temperature exceeding a pre-determined threshold. The TRCB switch of this example may further include a current limiting circuit configured to monitor current flow through the TRCB switch and turn the TRCB switch off in response to the monitored current exceeding a pre-defined threshold.

As used herein, use of the term “nominal” or “nominally” when referring to an amount means a designated or theoretical amount that may vary from the actual amount.

Embodiments of the methods described herein may be implemented in a system that includes one or more storage mediums having stored thereon, individually or in combination, instructions that when executed by one or more processors perform the methods. Here, the processor may include, for example, a system CPU (e.g., core processor) and/or programmable circuitry. Thus, it is intended that operations according to the methods described herein may be distributed across a plurality of physical devices, such as processing structures at several different physical locations. Also, it is intended that the method operations may be performed individually or in a subcombination, as would be understood by one skilled in the art. Thus, not all of the operations of each of the flow charts need to be performed, and the present disclosure expressly intends that all subcombinations of such operations are enabled as would be understood by one of ordinary skill in the art.

The storage medium may include any type of tangible medium, for example, any type of disk including floppy disks, optical disks, compact disk read-only memories (CD-ROMs), compact disk rewritables (CD-RWs), digital versatile disks (DVDs) and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of media suitable for storing electronic instructions.

The term “switches” may be embodied as MOSFET switches (e.g. individual NMOS and PMOS elements), BJT switches, diodes and/or other switching circuits known in the art. In addition, “circuitry” or “circuit”, as used in any embodiment herein, may comprise, for example, singly or in any combination, hardwired circuitry, programmable circuitry, state machine circuitry, and/or circuitry that is included in a larger system, for example, elements that may be included in an integrated circuit.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. A device, comprising:
a PMOS switch, comprising a source port, a drain port, a gate port and an n-well region;
an input voltage port coupled to said source port;
an output voltage port coupled to said drain port;
a switch control port coupled to said gate port; and
comparator circuitry configured to compare an input voltage at said input voltage port with an output voltage at said output voltage port and select a maximum of said input voltage and said output voltage, said comparator circuitry further configured to couple said selected maximum to said n-well region.

2. The device of claim 1, further configured to turn off said gate port in response to said comparator detecting that said output voltage exceeds said input voltage.

3. The device of claim 1, further comprising a first diode coupling said source port to said n-well region and a second diode coupling said drain port to said n-well region.

4. The device of claim 1, wherein said comparator circuitry is a cascode comparator comprising a two-stage amplifier.

5. The device of claim 1, further configured to de-couple said input voltage port from said output voltage port in response to said comparator detecting that said output voltage exceeds said input voltage.

6. The device of claim 1, further comprising a hysteresis circuit configured to reduce switching events generated in response to signal noise.

7. A method, comprising:
comparing an input voltage at a source port of a PMOS switch with an output voltage at a drain port of said PMOS switch;
selecting a maximum of said input voltage and said output voltage; and
coupling said selected maximum to an n-well region of said PMOS switch.

8. The method of claim 7, further comprising turning off a gate port of said PMOS switch in response to detecting that said output voltage exceeds said input voltage.

9. The method of claim 7, further comprising coupling a first diode between said source port and said n-well region and coupling a second diode between said drain port and said n-well region.

10. The method of claim 7, wherein said comparing is performed by a cascode comparator comprising a two-stage amplifier.

11. The method of claim 7, further comprising de-coupling said source port from said drain port in response to detecting that said output voltage exceeds said input voltage.

12. The method of claim 7, further comprising configuring a hysteresis circuit to reduce switching events generated in response to signal noise.

13. A system, comprising:
a true reverse current blocking (TRCB) switch comprising:
a PMOS switch, comprising a source port, a drain port, a gate port and an n-well region;
an input voltage port coupled to said source port;
an output voltage port coupled to said drain port;
a switch control port coupled to said gate port; and
comparator circuitry configured to compare an input voltage at said input voltage port with an output voltage at said output voltage port and select a maximum of said input voltage and said output voltage, said comparator circuitry further configured to couple said selected maximum to said n-well region;
a thermal shutdown circuit configured to monitor the temperature of said TRCB switch and turn said TRCB switch off in response to said monitored temperature exceeding a pre-determined threshold; and
a current limiting circuit configured to monitor current flow through said TRCB switch and turn said TRCB switch off in response to said monitored current exceeding a pre-defined threshold.

14. The system of claim 13, wherein said TRCB circuit is further configured to turn off said gate port in response to said comparator detecting that said output voltage exceeds said input voltage.

15. The system of claim 13, wherein said TRCB circuit further comprises a first diode coupling said source port to said n-well region and a second diode coupling said drain port to said n-well region.

16. The system of claim 13, wherein said comparator circuitry is a cascode comparator comprising a two-stage amplifier.

17. The system of claim 13, wherein said TRCB circuit is further configured to de-couple said input voltage port from said output voltage port in response to said comparator detecting that said output voltage exceeds said input voltage.

18. The system of claim 13, wherein said TRCB circuit further comprises a hysteresis circuit configured to reduce switching events generated in response to signal noise.
